(19) United States
(12) Patent Application Publication
(10) Pub. No.: US 2009/0032860 A1
(43) Pub. Date: Feb. 5, 2009

(54) PROGRAMMABLE MEMORY, PROGRAMMABLE MEMORY CELL AND THE MANUFACTURING METHOD THEREOF

(76) Inventors: Mao-Quan Chen, Changhua County (TW); Ching-Nan Hsiao, Kaohsiung County (TW); Chung-Lin Huang, Tao-Yuan City (TW); Hsi-Hua Chang, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 11/960,720

(22) Filed: Dec. 20, 2007

(30) Foreign Application Priority Data
Aug. 2, 2007 (TW) 096128393

(51) Int. Cl. H01L 29/788; H01L 21/336

(52) U.S. Cl. 257/316; 438/261; 257/E21.422; 257/E29.3

(57) ABSTRACT

A programmable memory structure includes a substrate, an active area, a common-source and a common-drain respectively disposed on each side of the active area, a first and a second source contact electrically connected to the common-source, a first and a second drain contact electrically connected to the common-drain, and between the first and the second source contact and the first and the second drain contact a plurality of programmable memory cells including a first and a second dielectric layer respectively encapsulating a first and a second floating gate.

### BACKGROUND OF THE INVENTION

1. Field of the Invention

The present invention relates to a memory, and more particularly, to a programmable memory and the manufacturing method thereof.

2. Description of the Prior Art

A flash memory is widely used because of its capability of non-volatile information storage. Generally speaking, a flash memory is divided into two groups, a NOR flash memory and a NAND flash memory. In the NOR flash memory, each memory cell is connected to a word line and a bit line.

In the flash memory, the floating gate is used to store the charge representing the data. Generally, the floating gate element is required to keep at a high coupling ratio. The “coupling ratio” means the charge coupling ratio of the dielectric layer between the floating gate and the control gate and the floating gate dielectric layer. The increase of the coupling ratio may lower the operational voltage and enhance the performance of the elements.

U.S. Pat. No. 6,724,029 provides a programmable memory cell structure. In this twin bit cell, only two sides of the rectangular floating gate region are covered by the control gate. The coupling ratio is low and the cell is large due to the length of the control gate.

On the other hand, U.S. Pat. No. 6,635,532 provides a method for manufacturing a NOR flash memory. In the obtained NOR flash memory, many drain contacts are required to maintain the electric connection of each drain because the drains are not common-drain and therefore, the drain contacts occupy the limited space on the substrate.

Accordingly, a novel programmable memory and a programmable memory cell are required to overcome the problems.

### SUMMARY OF THE INVENTION

The present invention provides a novel programmable memory which uses common-source and common-drain to increase the density of the cells on the substrate. Still, in the novel programmable memory there are novel programmable memory cells. The programmable memory cells are preferably twin bit cells. A special U-shaped dielectric layer caps the floating gate to increase the coupling ratio so as to lower the operational voltage and enhance the performance of the elements.

The present invention first provides a programmable memory cell including a substrate; a share control gate; a control gate dielectric layer disposed between the substrate and the share control gate; a first floating gate and a second floating gate respectively disposed on two opposed sides of the share control gate; a first floating gate dielectric layer disposed between the substrate and the first floating gate; a second floating gate dielectric layer disposed between the substrate and the second floating gate; a first dielectric layer surrounding side faces as well as the top faces of the first floating gate and contacting the share control gate; a second dielectric layer surrounding side faces as well as the top faces of the second floating gate and contacting the share control gate, wherein the share control gate simultaneously covers the first dielectric layer and the second dielectric layer; and a source/drain respectively disposed adjacent to the first floating gate dielectric layer and the second floating gate dielectric layer.

The present invention still provides a programmable memory structure including a substrate, an active area disposed on the substrate and extending along a first direction, a common-source and a common-drain respectively disposed on each side of the active area and extending along the first direction, a first and a second source contact electrically connected to the common-source, a first and a second drain contact electrically connected to the common-drain, and a plurality of programmable memory cells in the active area and between the first and the second source contact and the first and the second drain contact.

The present invention again provides a method for forming a dielectric structure in a programmable memory, including:

providing a substrate including a source doping region and a drain doping region on which a source insulation structure and a drain insulation structure are respectively formed and electrically connected to a common-source and a common-drain, and a floating gate oxide layer covering the exposed substrate;

conformally depositing a poly-Si layer on the source insulation structure, the drain insulation structure and the floating gate oxide layer;

etching the poly-Si layer to form a pair of corresponding first floating gate and second floating gate on the sidewalls of the source insulation structure and the drain insulation structure;

removing part of the source insulation structure and part of the drain insulation structure;

conformally depositing a dielectric layer on the source insulation structure, the drain insulation structure and the floating gate oxide layer;

selectively removing the dielectric layer to expose the source insulation structure, the drain insulation structure and the floating oxide gate layer to respectively form a first dielectric structure and a second dielectric structure;

forming a control gate dielectric layer on the floating oxide gate layer; and

forming a share control gate layer covering the source insulation structure, the drain insulation structure, the control gate dielectric layer, the first dielectric structure and the second dielectric structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a preferred embodiment of the programmable memory cells of the present invention.

FIG. 2 illustrates a preferred embodiment of the layout of the programmable memory structure of the present invention.

FIGS. 3-9 illustrate a method for forming a programmable memory of the present invention.

### DETAILED DESCRIPTION

In the novel programmable memory of the present invention, a common-source and a common drain are used to replace the conventional source and drain to increase the density of the cells on the substrate to lower the cost. Still, in the novel programmable memory, there are novel programmable memory cells, twin bit cells. A special U-shaped dielectric layer caps the floating gate to increase the coupling ratio so as to lower the operational voltage and enhance the performance of the elements.

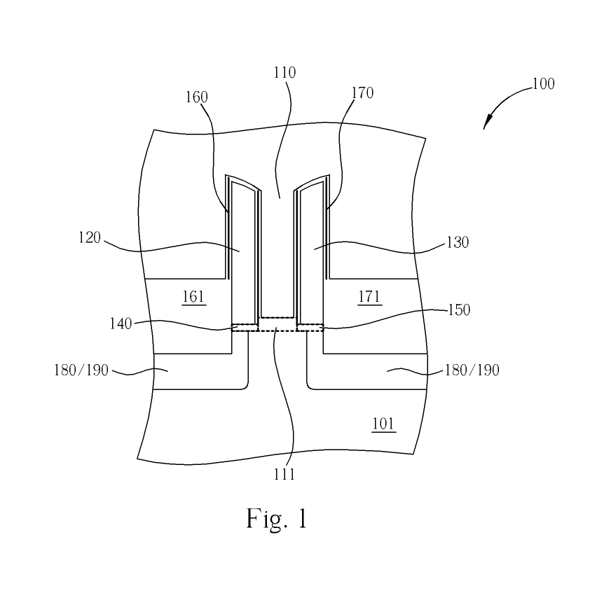

FIG. 1 illustrates a preferred embodiment of the programmable memory cells of the present invention. The programmable memory cells 100 of the present invention includes a substrate 101, a share control gate 110, a control gate dielectric layer 111, a first floating gate 120, a second floating gate 130, a first floating gate dielectric layer 140, a second floating gate dielectric layer 150, a first dielectric layer 160 and a second dielectric layer 170. A source/drain 180/190 is respectively disposed adjacent to the first floating gate dielectric layer 140 and the second floating gate dielectric layer 150.

The substrate 101 is usually a semiconductor substrate, such as Si. The share control gate 110 is shared by both the first floating gate 120 and the second floating gate 130 to control the first floating gate 120 and the second floating gate 130. The share control gate 110, the first floating gate 120 and the second floating gate 130 usually include doped poly-Si to be conductive. The control gate dielectric layer 111 is disposed between the substrate 101 and the share control gate 110 and made of high quality oxide, such as silicon oxide, with a thickness of 150 Å-300 Å.

As shown, the first floating gate 120 and the second floating gate 130 are respectively disposed on two opposed sides of the share control gate 110. The first floating gate dielectric layer 140 is disposed between the substrate 101 and the first floating gate 120, and the second floating gate dielectric layer 150 is disposed between the substrate 101 and the second floating gate 130. Both the first floating gate dielectric layer 140 and the second floating gate dielectric layer 150 are usually made of high quality oxide, such as silicon oxide, with a thickness of 70 Å-120 Å.

The first dielectric layer 160 and second dielectric layer 170, which respectively contact the share control gate 110, respectively cover the top and opposed sides of the first floating gate 120 and the second floating gate 130. Again, the share control gate 110 covers the first dielectric layer 160 and second dielectric layer 170, respectively. The first dielectric layer 160 and second dielectric layer 170 may independently include a multi-layer structure such as an oxide-nitride-oxide (ONO) composite dielectric structure.

The advantages of the programmable memory cells 100 of the present invention reside in that at least one of the dielectric layers encapsulates at least one of the floating gates in a special U-shaped manner so that the upper half of the floating gate is almost capped by the dielectric layer. Because the “coupling ratio” means the charge coupling ratio of the dielectric layer between the floating gate and the control gate and the floating gate dielectric layer, the increase of the coupling ratio may lower the operational voltage and enhance the performance of the elements.

If necessary, a first insulation structure 161 and a second insulation structure 171 may be disposed on the source/drain 180/190 and each contacts the first floating gate 120 and the second floating gate 130, respectively. The first insulation structure 161 and a second insulation structure 171 are usually made of high quality oxide.

If the first insulation structure 161 and a second insulation structure 171 exist, the first dielectric layer 160 and second dielectric layer 170 may asymmetrically cover the first floating gate 120 and the second floating gate 130 respectively, which is another structural feature of the programmable memory cells 100 of the present invention.

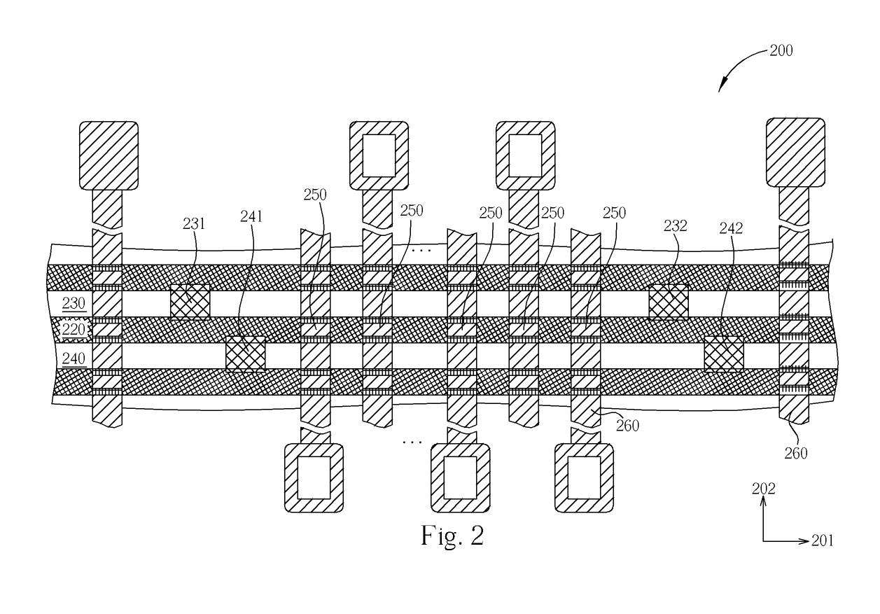

FIG. 2 illustrates a preferred embodiment of the layout of the programmable memory structure of the present invention. The programmable memory structure 200 includes a substrate on the bottom (not shown), an active area 220, a common-source 230, a common-drain 240, a first source contact 231, a second source contact 232, a first drain contact 241, a second drain contact 242 and programmable memory cells 250.

The substrate is usually a semiconductor substrate, such as Si. The active area 220 on the substrate extends along an arbitrary direction, i.e. a first direction 201. In addition, the common-source 230/common-drain 240 are respectively disposed on one side of the active area 220 and extends along the first direction 201.

A plurality of programmable memory cells 250 is disposed in the active area 220. The first source contact 231 and the second source contact 232 are respectively electrically connected to the common-source 230 at certain intervals. Similarly, the first drain contact 241 and the second drain contact 242 are respectively electrically connected to the common-drain 240 at certain intervals. Some programmable memory cells 250 are disposed among the first source contact 231, the second source contact 232, the first drain contact 241 and the second drain contact 242. The more programmable memory cells 250 there are among the first source contact 231, the second source contact 232, the first drain contact 241 and the second drain contact 242, the more efficiently the limited space on the substrate is used to increase the density of the cells on the substrate to lower the cost. For example, the programmable memory cells 250 may be more than 10, preferably more than 15 and more preferably more than 20, depending on the electric resistance of the materials of the common-source/common-drain.

Because the conventional source/drain are replaced by the common-source/common-drain, more space is available to increase the density of the cells on the substrate to lower the cost.

The programmable memory cells 250 may preferably include a dual floating gate structure, i.e. a twin bit cell structure. The programmable memory cell 250 may include, for example, a substrate; a share control gate; a control gate dielectric layer disposed between the substrate and the share control gate; a first floating gate and a second floating gate respectively disposed on two opposed sides of the share control gate; a first floating gate dielectric layer disposed between the substrate and the first floating gate; a second floating gate dielectric layer disposed between the substrate and the second floating gate; a first dielectric layer surrounding the first floating gate as well as the top thereof and contacting the share control gate; a second dielectric layer surrounding the second floating gate as well as the top thereof and contacting the share control gate, wherein the share control gate respectively covers the first dielectric layer and the second dielectric layer; and a source/drain respectively disposed adjacent to the first floating gate and the second floating gate, as shown in FIG. 1.

Besides, the programmable memory structure 200 may include a word line 260 which extends along a second direction 202 and is electrically connected to the share control gate in the programmable memory cell 250. Preferably, the first direction 201 is normal to the second direction 202. The dielectric layer preferably encapsulates the floating gate in a special U-shaped manner so that the upper half of the floating gate is almost capped by the dielectric layer. As a result, the increase of the coupling ratio effectively lowers the operational voltage and enhance the performance of the elements.

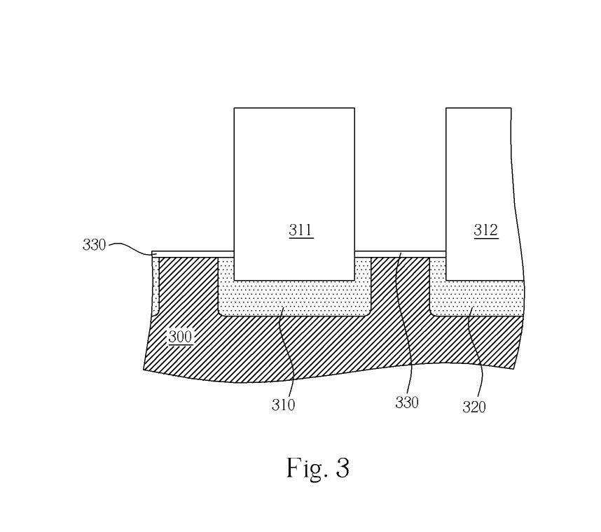

FIGS. 3-9 illustrate a method for forming a programmable memory of the present invention. First, a substrate 300 is provided, in which there are a source doping region 310 and a drain doping region 320 respectively connected to a common source (not shown) and a common drain (not shown) and on the source doping region 310 and on the drain doping region 320 there are a source insulation structure 311 and a drain insulation structure 312. Additionally, a floating gate oxide layer 330 covers an exposed surface of the substrate 300. The substrate is usually a semiconductor substrate, such as Si. The source insulation structure 311 and a drain insulation structure 312 are usually oxides, formed by high-density plasma chemical vapor deposition for example.

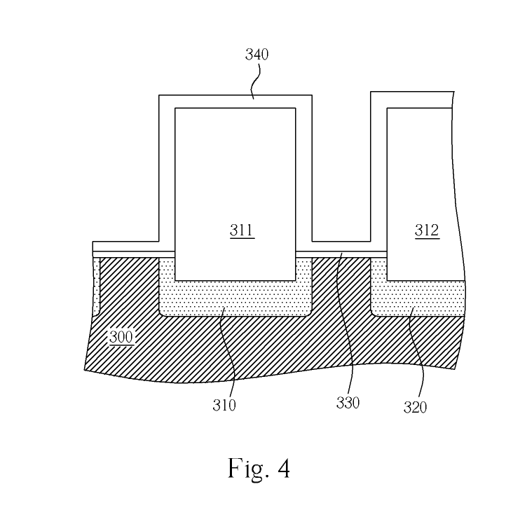

Later, as shown in FIG. 4, a poly-Si layer 340 is conformally deposited on the source insulation structure 311, the drain insulation structure 312 and the floating gate oxide layer 330. For example, the low pressure chemical vapor deposition (LPCVD) and in-situ implantation may be used to implant N-dopants so that the thickness of the poly-Si layer 340 is about 200 Å-300 Å.

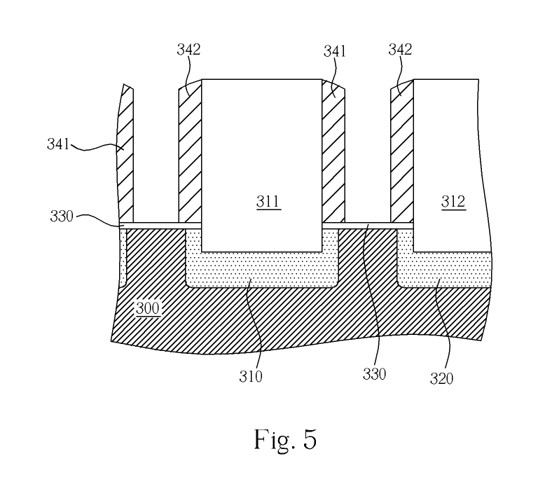

Then, as shown in FIG. 5, the excessive poly-Si layer 340 is etched away by dry etching to form a pair of corresponding first floating gate 341 and second floating gate 342 on two opposed sidewalls of the source insulation structure 311 and the drain insulation structure 312. After the dry etching, the top of the first floating gate 341 and second floating gate 342 are slightly inclined.

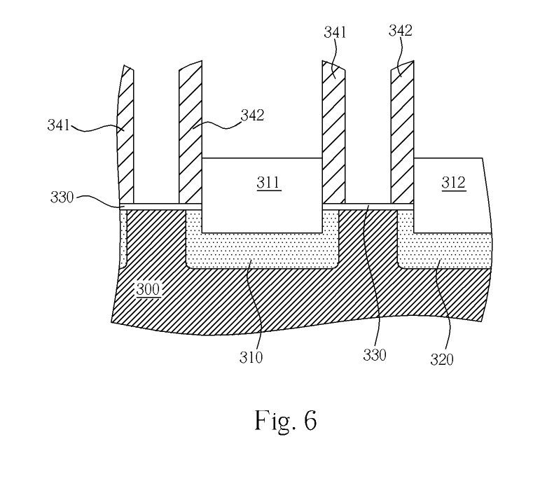

With reference to FIG. 6, another dry etching is used to remove part of the source insulation structure 311 and part of the drain insulation structure 312. Preferably, the height of the source insulation structure 311 and of the drain insulation structure 312 is 400 Å-800 Å over the substrate after the dry etching.

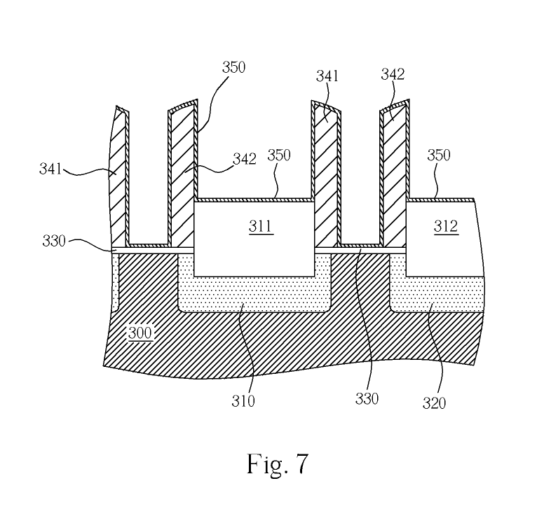

Afterwards, as shown in FIG. 7, a dielectric layer 350 is conformally deposited on the source insulation structure 311, the drain insulation structure 312 and the floating gate oxide layer 330 to have a thickness of about 100 Å-300 Å. Now, the dielectric layer 350 completely covers the first floating gate 341 and second floating gate 342. The dielectric layer 350 may include a multi-layer structure such as an oxide-nitride-oxide (ONO) composite dielectric structure.

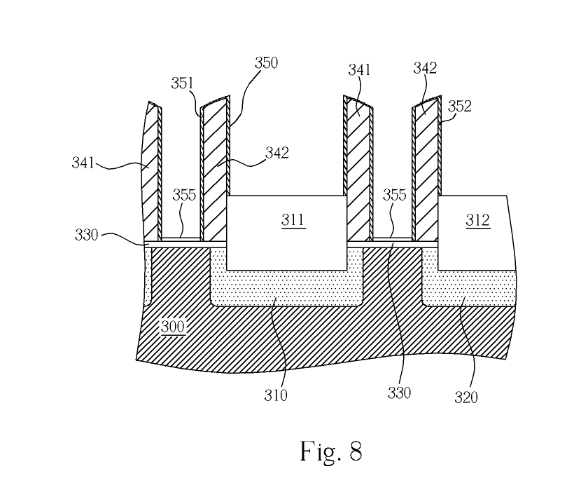

Subsequently, as shown in FIG. 8, the anisotropic dry etching is employed to selectively remove the dielectric layer 350 to expose the source insulation structure 311, the drain insulation structure 312 and the floating oxide gate layer 330 to respectively form a first dielectric structure 351 and a second dielectric structure 352. For the present, the dry etching may partly but not entirely diminish the thickness of the first dielectric structure 351 and the second dielectric structure 352. For example, when the dielectric layer 350 is an oxide-nitride-oxide (ONO) composite dielectric structure, at least one oxide layer remains.

Optionally, the substrate 300 covered by the first floating gate 341 and second floating gate 342 may be further implanted by dopants to adjust the threshold voltage (Vt). After this, a rapid thermo-oxidation (RTO) may be used to form the control gate dielectric layer 355 on the floating oxide gate layer 330 and to additionally increase the reliability of the first dielectric structure 351 and the second dielectric structure 352 on the first floating gate 341 and second floating gate 342. By now, the dielectric structure in the programmable memory of the present invention is done.

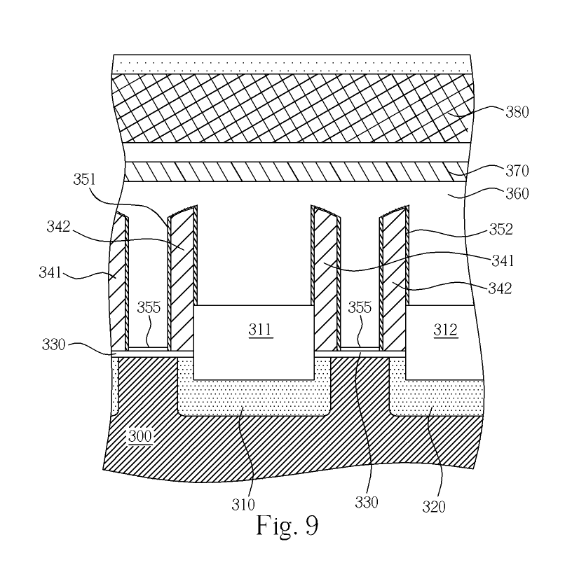

Then, as shown in FIG. 9, the share control gate layer 360 may be formed by LPCVD and covers the insulation structure 311, the drain insulation structure 312, the control gate dielectric layer 355, the first dielectric structure 351 and the second dielectric structure 352. The share control gate layer 360 usually includes doped poly-Si to be conductive.

Afterwards, the word line 370 made of silicide and the interlayer dielectric layer 380 may be further formed on the share control gate layer 360. Or, some source contacts respectively electrically connected to the common-source and some drain contacts respectively electrically connected to the common-drain may be formed as required.

Those skilled in the art will readily observe that numerous modifications and alternations of the device and method may be made while retaining the teachings of the invention.

What is claimed is:

1. A programmable memory cell, comprising:
a substrate;
a share control gate;
a control gate dielectric layer disposed between said substrate and said share control gate;
a first floating gate and a second floating gate respectively disposed on one side of said share control gate;
a first floating gate dielectric layer disposed between said substrate and said first floating gate;
a second floating gate dielectric layer disposed between said substrate and said second floating gate;
a first dielectric layer covering top and sides of said first floating gate and contacting said share control gate;
a second dielectric layer covering top and sides of said second floating gate and contacting said share control gate, wherein said share control gate respectively covers said first dielectric layer and said second dielectric layer; and
a source/drain respectively disposed adjacent to said first floating gate dielectric layer and said second floating gate dielectric layer.

2. The programmable memory cell of claim 1, wherein said first floating gate and said second floating gate respectively comprise poly-Si.

3. The programmable memory cell of claim 1, wherein said first dielectric layer comprises a first oxide-nitride-oxide (ONO) dielectric structure.

4. The programmable memory cell of claim 1, wherein said first dielectric layer asymmetrically covers said first floating gate.

5. The programmable memory cell of claim 1, wherein said second dielectric layer comprises a second oxide-nitride-oxide (ONO) dielectric structure.

6. The programmable memory cell of claim 4, wherein said second dielectric layer asymmetrically covers said first floating gate.

7. The programmable memory cell of claim 6, further comprising a first insulation structure and a second insulation structure disposed on said source/drain and said first floating gate and said second floating gate respectively contacting said first insulation structure and said second insulation structure.

8. A programmable memory structure, comprising:
a substrate;
an active area disposed on said substrate and extending along a first direction;
a common-source disposed on one side of said active area and extending along said first direction;
a common-drain disposed on another side of said active area and extending along said first direction;
a first source contact and a second source contact electrically connected to said common-source;
a first drain contact and a second drain contact electrically connected to said common-drain; and
a plurality of programmable memory cells disposed in said active area and between said first and said second source contact and said first and said second drain contact.

9. The programmable memory structure of claim 8, wherein said programmable memory cells comprise a dual floating gate structure.

10. The programmable memory structure of claim 8, wherein said programmable memory cells comprise:
a share control gate;
a control gate dielectric layer disposed between said substrate and said share control gate;
a first floating gate and a second floating gate respectively disposed on one side of said share control gate;
a first floating gate dielectric layer disposed between said substrate and said first floating gate;
a second floating gate dielectric layer disposed between said substrate and said second floating gate;
a first dielectric layer covering the top and both sides of said first floating gate and contacting said share control gate;
a second dielectric layer covering the top and both sides of said second floating gate and contacting said share control gate, wherein said share control gate respectively covers said first dielectric layer and said second dielectric layer; and
a source/drain respectively disposed adjacent to said first floating gate dielectric layer and said second floating gate dielectric layer.

11. The programmable memory structure of claim 8, wherein there are more than 10 of said programmable memory cells.

12. The programmable memory structure of claim 8, wherein said programmable memory cell comprises a share control gate.

13. The programmable memory structure of claim 12, further comprising a word line extending along a second direction and electrically connected to said share control gate.

14. The programmable memory structure of claim 13, wherein said first direction is normal to said second direction.

15. A method for forming a programmable memory, comprising:
providing a substrate comprising a source doping region and a drain doping region, a source insulation structure and a drain insulation structure respectively formed on said source doping region and said drain doping region and respectively electrically connected to a common source and a common drain, and a floating gate oxide layer covering said exposed substrate;
conformally depositing a poly-Si layer on said source insulation structure, said drain insulation structure and said floating gate oxide layer;
etching said poly-Si layer to form a pair of corresponding first floating gate and second floating gate on the sidewalls of said source insulation structure and said drain insulation structure;
removing part of said source insulation structure and part of said drain insulation structure;
conformally depositing a dielectric layer on said source insulation structure, said drain insulation structure and said floating gate oxide layer;
removing said dielectric layer to expose said source insulation structure, said drain insulation structure and said floating oxide gate layer to respectively form a first dielectric structure and a second dielectric structure;
forming a control gate dielectric layer on said floating oxide gate layer; and
forming a share control gate layer covering said source insulation structure, said drain insulation structure, said control gate dielectric layer and said first dielectric structure and said second dielectric structure.

16. The method for forming a programmable memory of claim 15, wherein said first dielectric structure comprises a first oxide-nitride-oxide (ONO) structure.

17. The method for forming a programmable memory of claim 15, wherein said second dielectric structure comprises a second oxide-nitride-oxide (ONO) structure.

18. The method for forming a programmable memory of claim 15, further comprising
forming a first source contact and a second source contact electrically connected to said common-source; and
a first drain contact and a second drain contact electrically connected to said common-drain.
